(19) United States
(12) Patent Application Publication
(10) Pub. No.: US 2022/0404441 A1
(43) Pub. Date: Dec. 22, 2022

(54) MAGNETIC FIELD SENSOR

(71) Applicant: Coventry University, Coventry (GB)

(72) Inventors: Soroush FARAMEHR, Coventry , West Midlands (GB); Peter IGIC, Coventry, West Midlands (GB)

(21) Appl. No.: 17/764,117

(22) PCT Filed: Jul. 16, 2020
(86) PCT No.: PCT/GB2020/051707

§ 371 Date: Mar. 25, 2022

(30) Foreign Application Priority Data
Sep. 27, 2019 (GB) 1913936.9

(51) Int. Cl. G01R 33/07; G01R 15/20; H01L 43/06

(52) U.S. Cl. CPC G01R 33/072; G01R 15/202; H01L 43/065

(57) ABSTRACT

A semiconductor device which comprises a substrate and a plurality of layers of semiconductor material. A primary region is provided which has a primary contact associated therewith. The device includes a secondary region which has first and second secondary contacts associated therewith. A conductive region is provided between the primary and secondary regions. An auxiliary contact is operably coupled to a current source and controls the flow of current through the semiconductor device dependent on temperature.

### TECHNICAL FIELD OF THE INVENTION

The present invention relates to semiconductor devices for use as magnetic field sensors. In particular, the invention relates to magnetic sensitive (Hall-effect) semiconductor devices operable to obtain a measurement of magnetic field strength, in use.

### BACKGROUND TO THE INVENTION

Magnetic sensors are used in numerous fields, including aerospace and automotive. Typically, magnetic field sensors may be operable to measure both current and/or magnetic field strength, for example, to ensure current running through a sensitive device does not exceed an acceptable level. Such devices may also be used to monitor frequency (and speed) of rotational components, for example. Magnetic sensitive field-effect transistors (MagFETs) are examples of such sensors.

MagFETs typically comprise a semiconductor device having a two drain outputs which are spatially separated. In use, charge carriers moving through the device will be deflected under the influence of an applied magnetic field. Therefore, by measuring variation in the current distribution between the two drain outputs, e.g. through detection of a current or voltage difference between the two drain outputs, a measure of the applied magnetic field can be made.

Recently, developments in magnetic sensitive sensor technology has realised a significant improvement in performance for sensors of this type. Specifically, moving from silicon (Si) to gallium nitride (GaN) based sensors—magnetic sensitive high-electron-mobility transistors (MagHEMTs)—has provided increased relative sensitivity, with values of around 14% being achieved compared with 3% relative sensitivity for Si based equivalents at comparable temperatures over a range of magnetic field strengths. At higher temperatures, e.g. temperatures in excess of the maximum operating temperature of Si sensors (˜120° C.), GaN sensors have been shown to have a relative sensitivity comparable to the performance of Si sensors at significantly lower temperatures. For example, a relative sensitivity of approximately 3% has been shown for a GaN sensor at 170° C.

However, the degradation in sensitivity of such sensors with temperature must be accounted for in order to provide accurate measurements of the current/magnetic field strength associated with a monitored device. Typically, this requires accurate modelling of a particular sensors sensitivity characteristics with temperature. Reduced sensitivity at higher temperatures can make it difficult to accurately model such characteristics, leading to reduced accuracy of the sensor, in use.

It would therefore be advantageous to provide a sensor which is operable over a range of temperatures with a substantially constant sensitivity.

It is an aim of an embodiment or embodiments of the invention to overcome or at least partially mitigate one or more problems associated with the prior art.

### SUMMARY OF THE INVENTION

According to an aspect of the invention there is provided a semiconductor device, comprising: a substrate; a plurality of layers of semiconductor material; a primary region having a primary contact associated therewith; a secondary region having first and second secondary contacts associated therewith; a conductive region between the primary and secondary regions; and an auxiliary contact operably coupled to a current source for controlling the flow of current through the semiconductor device, and wherein the current source is configured such that operation thereof is dependent on temperature.

Advantageously, the current flow through the semiconductor device may be controlled in dependence on temperature. Where the semiconductor device is operable as a sensor, e.g. a magnetic field sensor, the sensitivity of the sensor may be controlled via the current source. In this way, variations in temperature, e.g. in ambient temperature or operating temperature, can be accounted for with minimal or ideally no variation in sensitivity of the sensor.

The current source is operably coupled to the auxiliary contact for controlling current flow through the semiconductor device, for example, between the primary contact and the first and second secondary contacts and/or the auxiliary contact. For example, the current source may be configured to “enhance” or “oppose” the flow of current through the device, which may otherwise be increased or reduced due to temperature. The current source may be configured to maintain the current at a substantially constant value at all temperatures, or at least at all temperatures within an operating range of the semiconductor device and/or an operating range of an electrical component to be monitored by the semiconductor device. By controlling the current source in dependence on temperature, the sensitivity of the semiconductor device may be kept relatively constant for a range of temperatures.

The primary contact may, in embodiments, comprise a source electrode. In such embodiments, the primary region of the semiconductor device may comprise a source region.

In some embodiments the primary contact may span substantially the entire width of the semiconductor device. In other embodiments the primary contact may span only a portion of the width of the semiconductor device. The primary contact may be positioned substantially central with respect to the width of the semiconductor device. The primary contact may be positioned at an edge of the semiconductor device.

The first and second secondary contacts may be spatially separated within the semiconductor device. The first and second secondary contacts may be aligned along the length of the semiconductor device. In embodiments, the first and second secondary contacts may be positioned at opposing edges of the semiconductor device.

In embodiments, the first and second secondary contacts may comprise drain electrodes. In such embodiments, the secondary region of the semiconductor device may comprise a drain region.

In embodiments where the first and second secondary contacts comprise drain electrodes, the current distribution between the two drain electrodes may be indicative of a magnetic field applied to the semiconductor device. Accordingly, in such embodiments the semiconductor device may comprise or be operably connected to means for measuring the current distribution between the first and second secondary contacts. In this way, the semiconductor device may be operable as a magnetic field sensor for measuring the strength of a magnetic field applied thereto.

In embodiments wherein the first and second secondary contacts are positioned at opposing edges of the semiconductor device, the semiconductor device may comprise or be operably connected to means for measuring the voltage across the device between the first and second secondary contacts, where the voltage is indicative of the magnetic field applied to the semiconductor device. Specifically, the distribution of charge carriers within the device is altered in dependence on the strength of a magnetic field applied to the device, thereby giving rise to a potential difference across the device which may be measured via the first and second secondary contacts.

The auxiliary contact may be provided in a gap between the first and second secondary contacts. In alternate embodiments, the auxiliary contact may be spaced from the first and second secondary contacts. For example, in some embodiments the first and second secondary contacts may be provided at a first point along the length of the semiconductor device, with the auxiliary contact provided at a second point along the length of the semiconductor device.

In embodiments, the conductive region may comprise a high charge carrier density.

The width of the semiconductor may be substantially constant along its length. In other embodiments, the width of the semiconductor may vary along its length. As will be appreciated, the sensitivity of the semiconductor device may be dependent on the geometry of the device itself. Accordingly, the width of the semiconductor may be varied along its length to further control the sensitivity of the semiconductor device.

In embodiments the semiconductor device may comprise a gate contact. As will be appreciated, the gate contact may be provided across the conductive region to control mobility of charge carriers within the conductive region. The gate contact may be positioned between the primary contact and first and second secondary contacts.

The plurality of layers of semiconductor material may comprise a wide bandgap semiconductor material. The wide bandgap semiconductor material may comprise any one or more of: aluminium gallium arsenide (AlGaAs) and gallium arsenide (GaAs); aluminium gallium nitride (AlGaN) and gallium nitride (GaN); AlGaN and AlGaN; zinc oxide (ZnO) and gallium zinc oxide (GaZnO); and indium aluminium nitride (InAlN) and GaN. These material combinations can be deposited (or grown) on different substrates including, but not limited to, silicon (Si), silicon carbide (SiC), GaN, glass, diamond, and sapphire.

In embodiments, the plurality of layers of semiconductor materials contains a two-dimensional charge carrier (e.g. electron or hole) layer between two respective layers of the plurality of layers of semiconductor material.

In embodiments the current source may comprise a dependent current source. For example, in some embodiments the current source may comprise a voltage-controlled current source (VCCS). In other embodiments the current source may comprise a current-controlled current source (CCCS).

In embodiments, the current source may be operably connected to a temperature sensor. The temperature sensor may be operable to monitor an ambient temperature. The temperature sensor may be operable to monitor an operating temperature of the semiconductor device. The temperature sensor may be operable to monitor an operating temperature of an electrical component associated with the semiconductor device—e.g. the electrical component monitored by the semiconductor device, in use. In embodiments, the current source may be directly or indirectly connected to a temperature sensor.

The semiconductor device may be controllable by means of a control unit operably connected to the semiconductor device. In embodiments, the control unit may include one or more processors (e.g. electronic processors) configured to execute one or more instructions for controlling operation of the semiconductor device in accordance with the one or more instructions. The one or more instructions may be stored in a memory means associated with the control unit—e.g. a local or remote memory means accessible by the control unit.

In some embodiments the control unit may be configured to execute one or more instructions for controlling operation of the current source.

The control unit may include one or more inputs (e.g. electrical inputs) for receiving one or more signals. The one or more signals may, in embodiments, be indicative of the temperature monitored by a temperature sensor operably connected to the control unit. The control unit may include one or more outputs (e.g. an electrical output) for outputting one or more control signals. The one or more control signals may, in embodiments, comprise instructions for controlling operation of the current source—e.g. instructions for controlling operation of the current source in dependence on the temperature monitored by a temperature sensor.

According to an aspect of the invention there is provided an electrical component comprising or being otherwise associated with a semiconductor device according to any preceding aspect of the invention, wherein the semiconductor device is configured to monitor operation of the electrical component by obtaining a measurement of a magnetic field produced by the electrical component, in use.

The electrical component may comprise a power switch, with the semiconductor device comprising an integrated sensor operable to monitor an output current of the power switch through galvanic current monitoring technique. Alternatively, the electrical component can comprise an electric machine driver, or a battery charger, for example, wherein the semiconductor device can be employed as a discrete sensor for current measurement. In further embodiments the electrical component may comprise an open or closed loop power transducers at high or cryogenic temperatures.

According to another aspect of the invention there is provided a method for monitoring operation of an electrical component using the semiconductor device of any preceding aspect of the invention, the method comprising: obtaining a measurement of the deflection of charge carriers within the semiconductor device; determining a magnetic field strength in dependent on the measurement of deflection of charge carriers within the semiconductor device; and determining an operational state of the electrical component in dependence on the determined magnetic field strength; wherein the method further comprises controlling operation of the current source in dependence on temperature to control current flow through the device to control the sensitivity of the semiconductor device.

In embodiments, obtaining a measurement of the deflection of charge carriers within the semiconductor device comprises determining a current distribution between the first and second secondary contacts. In other embodiments, obtaining a measurement of the deflection of charge carriers within the semiconductor device comprises determining a voltage between the first and second secondary contacts.

The method may comprise monitoring an ambient temperature and controlling operation of the current source in dependence on the ambient temperature. The method may comprise monitoring an operating temperature of the semiconductor device and controlling operation of the current source in dependence on the operating temperature of the semiconductor device. The method may comprise monitoring an operating temperature of the electrical component and controlling operation of the current source in dependence on the operating temperature of the electrical component.

### DETAILED DESCRIPTION OF THE INVENTION

In order that the invention may be more clearly understood one or more embodiments thereof will now be described, by way of example only, with reference to the accompanying drawings, of which:

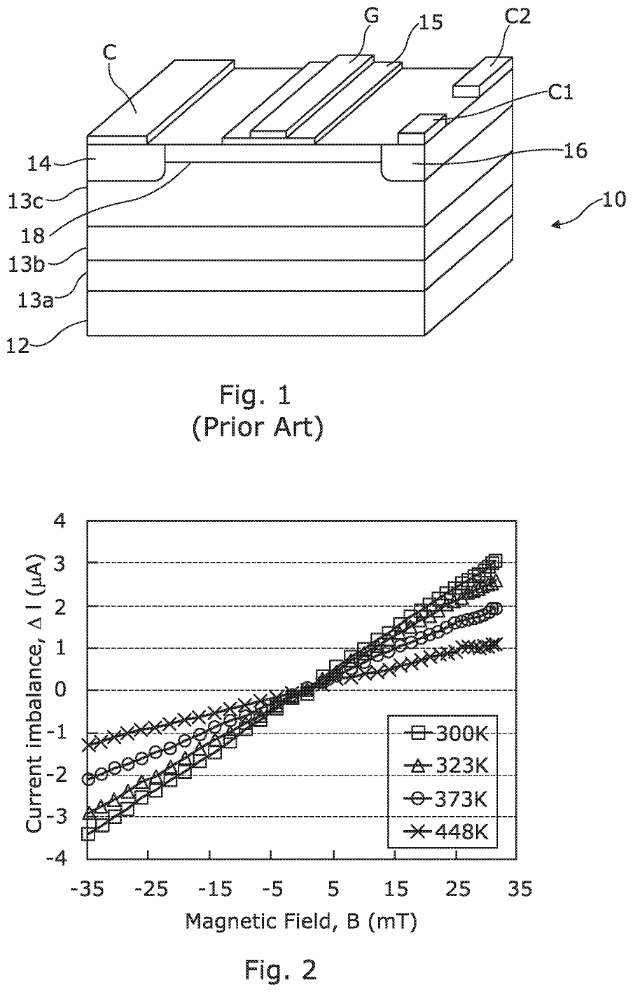

FIG. 1 is a perspective view of a prior art semiconductor device;

FIG. 2 is a graph illustrating how current imbalance between first and second drain contacts varies with magnetic field over a range of temperatures in the semiconductor device of FIG. 1;

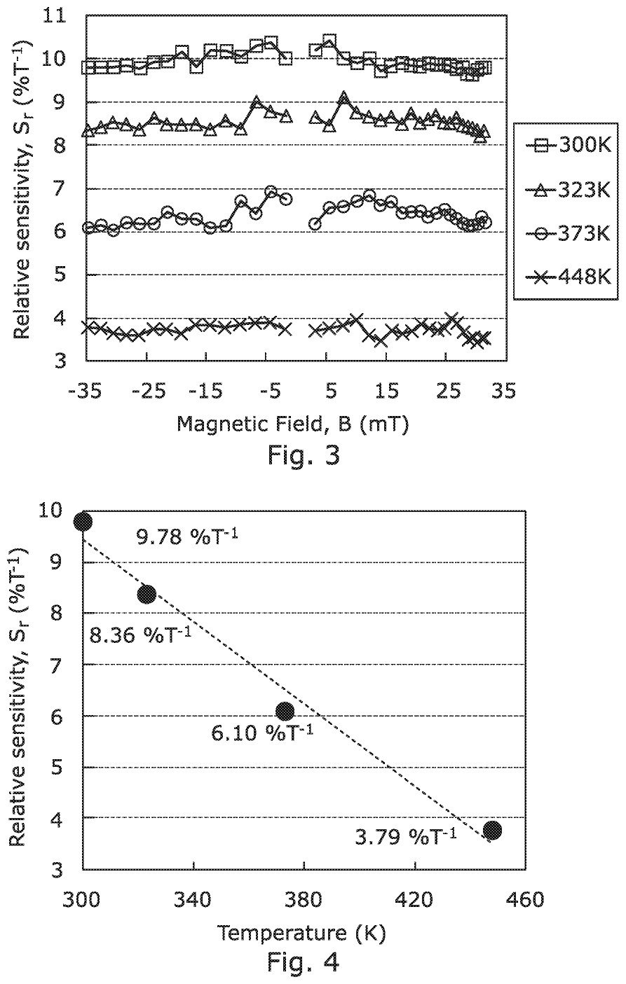

FIG. 3 is a graph illustrating how the relative sensitivity S of the semiconductor device of FIG. 1 varies with magnetic field over a range of temperatures;

FIG. 4 is a graph illustrating how the relative sensitivity S of the semiconductor device of FIG. 1 varies with temperature;

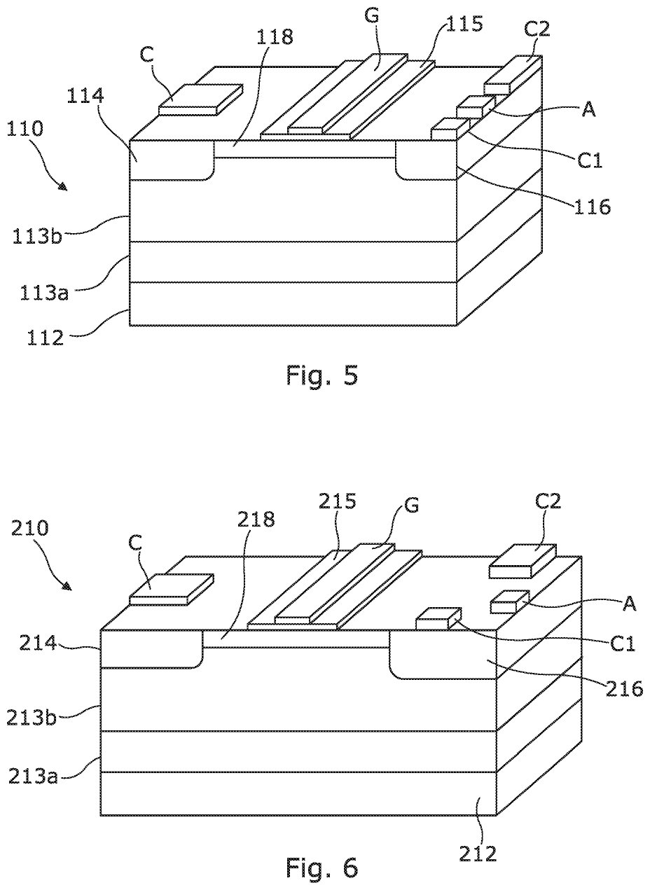

FIG. 5 is a perspective view of an embodiment of a semiconductor device of the invention;

FIG. 6 is a perspective view of a further embodiment of a semiconductor device of the invention;

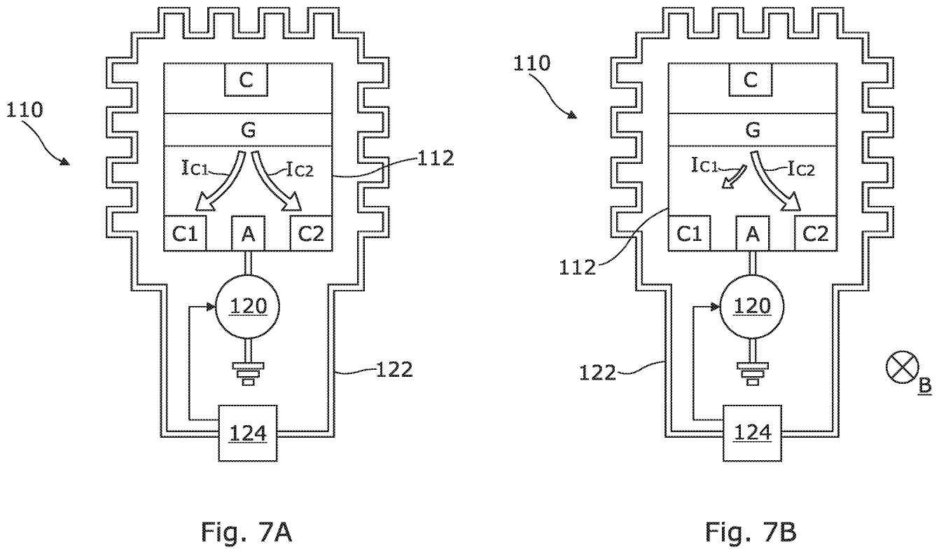

FIGS. 7A-7B are schematic views of the semiconductor device of FIG. 5 illustrating its operational use;

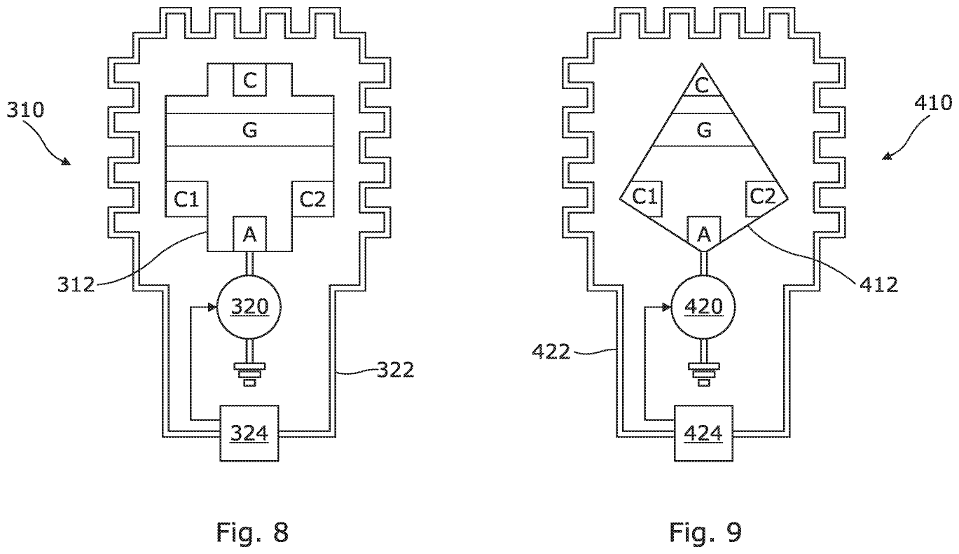

FIG. 8 is a schematic view of a variant of the semiconductor device shown in FIGS. 7A and 7B; and

FIG. 9 is a schematic view of a further variant of the semiconductor device shown in FIGS. 7A and 7B.

In general, the present invention relates to a semiconductor device 110, 210, 310, 410 which includes a substrate 112, 212, 312, 412 and a plurality of layers 113, 213, 313, 413 of semiconductor material. A primary contact C and first and second secondary contacts C1, C2 are provided along with an auxiliary contact A. In use, the auxiliary contact A is operably coupled to a current source 120, 320, 420 for controlling the flow of current through the semiconductor device 110, 210, 310, 410 which, in turn, is controllable in dependence on temperature which may be measured by a temperature sensor 122, 322, 422.

Advantageously, the current flow through the semiconductor device 110, 210, 310, 410 may be controlled in dependence on temperature. Where the semiconductor device 110, 210, 310, 410 is operable as a sensor, e.g. a magnetic field sensor, the sensitivity of the sensor 110, 210, 310, 410 may be controlled via the current source 120, 320, 420. In this way, variations in temperature, e.g. in ambient temperature or operating temperature, can be accounted for with minimal or ideally no variation in sensitivity of the sensor 110, 210, 310, 410.

FIG. 1 illustrates a prior art semiconductor device 10. The device 10 includes a substrate 12 and a plurality of layers 13a, 13b, 13c of semiconductor material. In the illustrated embodiment, the semiconductor materials include GaN and AlGaN. As discussed herein, devices formed from such materials have been shown to exhibit significantly higher relative sensitivity values than silicon based devices.

A primary contact C and first and second secondary contacts C1, C2 are provided, along with a gate contact G electrically isolated from the remainder of the device 10 via insulting layer 15. A primary region 14—e.g. a source region—within layer 13c is associated with the primary contact C. A secondary region 16—e.g. a drain region—within layer 13c is associated with the secondary contacts C1, C2. A conductive region 18 is provided between the primary region 14 and secondary region 16.

In use, the current distribution between secondary contacts C1 and C2 is indicative of a magnetic field B present. With no B field present the current through the device 10 will be equally split between secondary contacts C1 and C2. However, upon the presence of a magnetic field B charge carriers within the device 10 experience a Lorentz force perpendicular to their direction of motion and perpendicular to the direction of the B field. The Lorentz force is proportional to the strength of the B field. This redistribution of charge carriers within the device 10 under the applied Lorentz force adjusts the current distribution between secondary contacts C1, C2, thereby leading to a measureable quantity indicative of the B field present. Specifically, the current imbalance ΔI between the output current at the first secondary contact C1 and the output current at the second secondary contact C2 is indicative of the magnetic field strength present as per equation 1, below.

B∝I_{C2}−I_{C1}=ΔI [Equation 1]

Further, a relative sensitivity S of the semiconductor device 10 can be defined, as follows.

$$S [ \% {T}^{- 1} ] = \frac{Δ I}{{I}_{C 1} + {I}_{C 2}} \times \frac{1}{\vert B \vert} \times 100 \% \qquad [ Equation 2 ]$$

FIG. 2 illustrates how the current imbalance ΔI between first and second drain contacts varies with magnetic field, and for a range of temperatures in the semiconductor device 10 of FIG. 1. As shown, the current imbalance ΔI varies substantially linearly with magnetic field. However, at increased temperatures the rate at which ΔI changes with magnetic field is shown to decrease. The effect of this on the relative sensitivity of the device 10 is shown in FIGS. 3 and 4.

Specifically, FIGS. 3 and 4 illustrate how the relative sensitivity S of the semiconductor device 10 varies with magnetic field over a range of temperatures. As shown in FIG. 3, for any given temperature the relative sensitivity S is roughly constant with magnetic field. However, as temperature increases the relative sensitivity of the device 10 drops. At 300K, roughly room temperature, the relativity sensitivity of the GaN based device 10 is approximately 10%, however, at elevated temperatures—e.g. 450K—the relative sensitivity of the device 10 drops to around 3.75% comparable with silicon based devices at lower temperatures.

It is understood that the relative decrease in electron mobility with increasing temperatures is likely to be the main contributor to a corresponding reduction in the drain current and transconductance of the device, and therefore the relative sensitivity.

As discussed herein, this degradation in sensitivity of such devices with temperature must be accounted for in order to provide accurate measurements of the magnetic field strength associated with a monitored electrical component. Typically, this would require accurate modelling of a particular devices sensitivity characteristics with temperature. Reduced sensitivity at higher temperatures can make it difficult to accurately model such characteristics, leading to reduced accuracy of the device, in use.

FIGS. 5-9 illustrate embodiments of semiconductor devices 110, 210, 310, 410 in accordance with the invention which attempt to mitigate this problem.

A first embodiment of a semiconductor device 110 is shown in FIGS. 5, 7A and 7B. The device 110 is similar in structure to the device 10 shown in the preceding figures, and comprises a substrate 112 and a plurality of layers 113a, 113b of semiconductor material. In the illustrated embodiment, the semiconductor materials include GaN and AlGaN although other materials may be equally applicable.

A primary contact C and secondary contacts C1 and C2 are provided, along with a gate contact G insulated from the remainder of the device 110 via insulting layer 115. A primary region 114—e.g. a source region—within layer 113b is associated with the primary contact C. A secondary region 116—e.g. a drain region—within layer 113b is associated with the secondary contacts C1, C2. A conductive region 118 is provided between the primary region 114 and secondary region 116.

As with semiconductor device 10, in use, the current distribution between secondary contacts C1 and C2 is indicative of a magnetic field, B present. Specifically, the current imbalance ΔI between the output current at the first secondary contact C1 and the output current at the second secondary contact C2 is indicative of the magnetic field strength present as per equation 1.

This is shown figuratively in FIGS. 7A and 7B. In particular, FIG. 7A shows semiconductor device 110 with no magnetic field B present. Here, the current imbalance ΔI is 0, with equal output current from both the first and second secondary contacts C1, C2. Upon the application of a field B, e.g. during operation of an associated electrical component, here shown in the direction perpendicular to the device 110, the distribution of charge carriers within the device 110 is altered under the influence of a Lorentz force as discussed above. This results in a current imbalance ΔI>0 proportional to the strength of the magnetic field present. This is shown in FIG. 7B where I_{C2}>I_{C1}. By measuring this current imbalance current imbalance ΔI, the strength of the magnetic field can be determined.

The semiconductor device 110 shown herein differs from device 10 in the provision of an auxiliary contact A. As shown, in this embodiment the auxiliary contact A is provided between the first and second secondary contacts C1, C2. In use, and as shown in FIGS. 7A and 7B, the auxiliary contact A is operably coupled to a current source 120 for controlling the flow of current through the semiconductor device 110. Further, operation of the current source 120 is controllable in dependence on temperature measured by a temperature sensor 122 operably connected to the current source 120.

Specifically, the current source 120 is operably coupled to the auxiliary contact A for controlling current flow through the semiconductor device 110 between the primary contact C and the first and second secondary contacts C1 and C2. In this way, the semiconductor device 110 is configured such that operation of the current source 120 may be controlled to “enhance” or “oppose” the flow of current through the device 110, which may otherwise be increased or reduced due to temperature. In this way, the current flow through the device 110 may be maintained at a substantially constant value at all temperatures, or at least at all temperatures within an operating range of the semiconductor device 110 and/or an operating range of an electrical component being monitored by the semiconductor device 110. In this way, the sensitivity of the semiconductor device 110 may be kept relatively constant for a range of temperatures.

Operation of the current source 120 is controlled via control unit 124 which is operably connected to both the current source 120 and the temperature sensor 122. The control unit 124 includes an electronic processor (not shown) configured to execute one or more instructions for controlling operation of the current source 120 in accordance with the one or more instructions. As will be appreciated, the one or more instructions may be stored in a memory means associated with the control unit 124—e.g. a local or remote memory means accessible by the control unit 124.

The control unit 124 is operably connected to the current source 120 via an electrical output and to the temperature sensor 122 via an electrical input. One or more signals may be received at the electrical input indicative of the temperature monitored by the temperature sensor 122. Similarly, the control unit 124 may be configured to output a control signal via electrical output for controlling operation of the current source 120 in dependence on the temperature monitored by a temperature sensor 122.

FIGS. 6, 8 and 9 show further embodiments of semiconductor devices 210, 310, 410 in accordance with the invention.

The devices 210, 310, 410 shown in these figures are substantially similar to the device 110 shown in FIGS. 5, 7A and 7B, and like reference numerals have been used to represent like components.

In each of devices 210, 310, 410 the first and second secondary contacts C1, C2 are positioned “ahead” of the auxiliary contact A with respect to the current flow through the device 210, 310, 410. Specifically, first and second secondary contacts C1, C2 are provided at a first point along the length of the device 210, 310, 410, whereas auxiliary contact A is provided at a second point along the length of the device 210, 310, 410.

Semiconductor device 210 shown in FIG. 6 comprises a substantially rectangular configuration, similar to device 110 shown in FIG. 5. However, the secondary contacts C1 and C2 are displaced from the auxiliary contact A along the length of the device 210.

Semiconductor devices 310, 410 shown in FIGS. 8 and 9 each comprise somewhat irregular (i.e. non-rectangular) configurations. As will be appreciated, the sensitivity of a semiconductor device is proportional to a number of variables, including the geometry of the device due to the effect the geometry of the device has on the distribution of charge carriers within the device. Accordingly, the sensitivity of a semiconductor device may further be altered through suitable configuration of its geometry.

Semiconductor device 310 shown in FIG. 8 again is substantially rectangular in configuration. However, the primary region 314 and at least part of the secondary region 316 of the device 310 may have a width which is less than the remainder of the device 310. Here, the secondary contacts C1, C2 are provided at a point along the length of the device 310 which is wider in width to maintain the separation of the secondary contacts C1, C2. This particular arrangement, particularly by reducing the size of the primary (e.g. source) region 314 but maintaining the separation of the secondary contacts C1, C2 may increase sensitivity of the device 310 further by providing an optimal or at least improved current path for the charge carriers through the device 310.

Semiconductor device 410 shown in FIG. 9 again is substantially triangular in configuration. The device 410 includes a primary region 414 which is further reduced in width when compared with device 310 shown in FIG. 8. The secondary contacts C1, C2 are provided at the widest point along the length of the device 410 to maintain/maximise the separation of the secondary contacts C1, C2. This particular arrangement, particularly by reducing the size of the primary (e.g. source) region 414 further, but again maintaining the separation of the secondary contacts C1, C2 may increase sensitivity of the device 410 further by providing an optimal or at least improved current path for the charge carriers through the device 410.

Whilst the devices 210, 310, 410 may be operable in substantially the same way as device 110 described above, the arrangements shown in these figures may be particularly useful where secondary contacts C1 and C2 are used to measure a voltage across the device 210, 310, 410 upon the presence of a magnetic field B, rather than the current distribution. This makes use of the fact that the distribution of charge carriers within the device 210, 310, 410 is altered in dependence on the strength of a magnetic field applied to the device 210, 310, 410, again due to the Lorentz force. This redistribution of charge carriers within the device 210, 310, 410 gives rise to a potential difference across the device 210, 310, 410 which may be measured via the first and second secondary contacts C1, C2. For example, the secondary contacts C1, C2 may be operably connected to means for measuring the voltage across the device between the first and second secondary contacts C1, C2, with the voltage measured being proportional to the magnetic field applied to the semiconductor device.

It will be appreciated that whilst sensors 110, 210, 310, 410 have been shown herein to be gated—i.e. via gate contact G—the sensors 110, 210, 310, 410 may equally be ungated.

The one or more embodiments are described above by way of example only. Many variations are possible without departing from the scope of protection afforded by the appended claims.

1. A semiconductor device, comprising: a substrate; a plurality of layers of semiconductor material; a primary region having a primary contact associated therewith; a secondary region having first and second secondary contacts associated therewith; a conductive region between the primary and secondary regions; and an auxiliary contact operably coupled to a current source for controlling the flow of current through the semiconductor device, and wherein the current source is configured such that operation thereof is dependent on temperature.

2. A semiconductor device as claimed in claim 1, wherein the current source is operably coupled to the auxiliary contact for controlling current flow through the semiconductor device between the primary contact and the first and second secondary contacts and/or the auxiliary contact

3. A semiconductor device as claimed in claim 1 or claim 2, wherein the current source is configured to maintain the current at a substantially constant value at all temperatures within an operating range of the semiconductor device and/or an operating range of an electrical component to be monitored by the semiconductor device.

4. A semiconductor device as claimed in any preceding claim, wherein the primary contact is positioned substantially central with respect to the width of the semiconductor device.

5. A semiconductor device as claimed in any preceding claim, wherein the first and second secondary contacts are spatially separated within the semiconductor device.

6. A semiconductor device as claimed in claim 5, wherein the first and second secondary contacts are aligned along the length of the semiconductor device.

7. A semiconductor device as claimed in claim 5 or claim 6, wherein the first and second secondary contacts are positioned at opposing edges of the semiconductor device.

8. A semiconductor device as claimed in any preceding claim, wherein the first and second secondary contacts comprise drain electrodes, and the current distribution between the two drain electrodes, in use, is indicative of a magnetic field applied to the semiconductor device.

9. A semiconductor device as claimed in claim 8, comprising or being operably connected to means for measuring the current distribution between the first and second secondary contacts.

10. A semiconductor device as claimed in claim 7, wherein comprising or being operably connected to means for measuring the voltage across the device between the first and second secondary contacts, where the voltage is indicative of the magnetic field applied to the semiconductor device.

11. A semiconductor device as claimed in any preceding claim, wherein the auxiliary contact is provided in a gap between the first and second secondary contacts.

12. A semiconductor device as claimed in any one of claims 1 to 10, wherein the first and second secondary contacts are provided at a first point along the length of the semiconductor device, with the auxiliary contact provided at a second point along the length of the semiconductor device.

13. A semiconductor device as claimed in any preceding claim, wherein the width of the semiconductor is substantially constant along its length.

14. A semiconductor device as claimed in any of claims 1 to 12, wherein the width of the semiconductor varies along its length.

15. A semiconductor device of any preceding claim, comprising a gate contact.

16. A semiconductor device of any preceding claim, wherein the plurality of layers of semiconductor material comprise a wide bandgap semiconductor material.

17. A semiconductor device of claim 16, wherein the wide bandgap semiconductor material comprises any one or more of: aluminium gallium arsenide (AlGaAs) and gallium arsenide (GaAs); aluminium gallium nitride (AlGaN) and gallium nitride (GaN); AlGaN and AlGaN; zinc oxide (ZnO) and gallium zinc oxide (GaZnO); and indium aluminium nitride (InAlN) and GaN.

18. A semiconductor device as claimed in any preceding claim, wherein the current source comprises a voltage-controlled current source (VCCS) or a current-controlled current source (CCCS).

19. A semiconductor device as claimed in any preceding claim, wherein the current source is operably connected to a temperature sensor.

20. A semiconductor device as claimed in any preceding claim controllable by means of a control unit operably connected to the semiconductor device.

21. An electrical component comprising or being otherwise associated with a semiconductor device according to any preceding claim, wherein the semiconductor device is configured to monitor operation of the electrical component by obtaining a measurement of a magnetic field produced by the electrical component, in use.

22. A method for monitoring operation of an electrical component using the semiconductor device of any preceding aspect of the invention, the method comprising:
obtaining a measurement of the deflection of charge carriers within the semiconductor device;
determining a magnetic field strength in dependent on the measurement of deflection of charge carriers within the semiconductor device; and
determining an operational state of the electrical component in dependence on the determined magnetic field strength;
wherein the method further comprises controlling operation of the current source in dependence on temperature to control current flow through the device to control the sensitivity of the semiconductor device.

23. A method as claimed in claim 22, wherein obtaining a measurement of the deflection of charge carriers within the semiconductor device comprises:
determining a current distribution between the first and second secondary contacts; or
determining a voltage between the first and second secondary contacts.

24. A method as claimed in claim 22 or 23, comprising monitoring an operating temperature of the semiconductor device and controlling operation of the current source in dependence on the operating temperature of the semiconductor device.
